(19) United States
(12) Patent Application Publication
(10) Pub. No.: US 2025/0092516 A1
(43) Pub. Date: Mar. 20, 2025

(54) SUBSTRATE PROCESSING APPARATUS WITH FLOW CONTROL RING AND METHOD OF USING SAME

(71) Applicant: ASM IP Holding B.V., Almere (NL)

(72) Inventors: Nirmal Gokuldas Waykole, Tempe, AZ (US); Jereld Lee Winkler, Gilbert, AZ (US); Yeonsu Rhee, Phoenix, AZ (US); Jonathan Bakke, Phoenix, AZ (US); Shubham Garg, Gilbert, AZ (US); Arjav Prafulkumar Vashi, Tempe, AZ (US); Qi Qi, Phoenix, AZ (US); Shuaidi Zhang, Chandler, AZ (US); Joshua Tyler Aragon, Laveen, AZ (US); Chen Zhang, Phoenix, AZ (US)

(21) Appl. No.: 18/884,515

(22) Filed: Sep. 13, 2024

Related U.S. Application Data
(60) Provisional application No. 63/538,611, filed on Sep. 15, 2023.

(51) Int. Cl. C23C 16/44; C23C 16/455; C23C 16/458

(52) U.S. Cl. CPC C23C 16/4409; C23C 16/45587; C23C 16/4582

(57) ABSTRACT

A substrate processing apparatus includes an upper chamber space, a lower chamber space, a susceptor, and a flow control ring assembly comprising a seal ring and a flow control ring having a shape to surround the susceptor, the flow control ring assembly sealing or substantially sealing the upper chamber space from the lower chamber space while the susceptor in a first position.

### CROSS-REFERENCE TO RELATED APPLICATIONS

This application is a nonprovisional of, and claims priority to and the benefit of, U.S. Provisional Patent Application No. 63/538,611 filed Sep. 15, 2023 and entitled “SUBSTRATE PROCESSING APPARATUS WITH FLOW CONTROL RING AND METHOD OF USING SAME,” which is hereby incorporated by reference herein.

### FIELD

Examples are described that relate to a flow control ring assembly and a substrate processing apparatus with a flow control ring assembly, as well as a method for use of the flow control ring assembly and substrate processing apparatus.

### BACKGROUND

A substrate processing apparatus, such as a gas-phase reactor, can often include an upper chamber space for processing a substrate and a lower chamber space for loading and unloading the substrate. During processing, if there is not a substantial seal between the upper chamber space and the lower chamber space, reaction gases may undesirably flow between the upper chamber space and the lower chamber space. The undesired flow of reaction gases between the chamber spaces can cause particle contamination and/or slower processing of the substrates.

In some cases, a flow control ring assembly can be used to separate the upper chamber space from the lower chamber space. However, such flow control ring assemblies may not provide desired isolation between the chambers. Accordingly, improved flow control ring assemblies are generally desired.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Examples described herein provide a substrate processing apparatus and a substrate processing method. Various examples of the substrate processing apparatus and substrate processing method provide reduced gas flow between an upper chamber space and a lower chamber space during substrate processing. Additional aspects will be set forth in part in the description which follows and, in part, will be apparent from the description, or may be learned by practice of the presented embodiments of the disclosure.

According to one or more embodiments, a substrate processing apparatus is provided. An exemplary substrate processing apparatus includes an upper chamber, a lower chamber, a susceptor, a flow control ring, and a spacer plate. The exemplary substrate processing apparatus further includes a seal ring or at least one gasket. The susceptor can be configured to hold a substrate. The susceptor can include a top surface and a ledge protruding from a side of the susceptor. The flow control ring can include an annular center region, a first portion disposed on the top surface, a second portion disposed on the ledge, and a third portion comprising a recess. The seal ring can be disposed in the recess. In other examples, the flow control ring can include one or more recesses. In some examples, one or more gaskets can be disposed in the one or more recesses. In some examples, the flow control ring can include two recesses. In such cases, one gasket can be disposed in each recess. The gasket can be made of a mica-based material, such as Micatherm SO or Micatherm S15.

In accordance with examples of these embodiments, the substrate processing apparatus can include a susceptor motor configured to raise and lower the susceptor from at least a first position to a second position. According to additional examples, the seal ring contacts the spacer plate when the susceptor is in the first position, and the seal ring seals or substantially seals the upper chamber from the lower chamber when the susceptor is in the first position. According to other additional examples, the at least one gasket contacts the spacer plate when the susceptor is in the first position, and the at least one gasket seals or substantially seals the upper chamber from the lower chamber when the susceptor is in the first position.

According to further examples, the seal ring is annular, and the seal ring comprises a body and at least two compressible members extending from the body. According to one or more examples, the at least two compressible members of the seal ring extend horizontally (e.g., substantially along a plane parallel to the top surface) from the body. According to one or more examples, the at least two compressible members can be compressed when the susceptor is in the first position.

According to yet further examples, the seal ring is annular, and a cross-section of the seal ring is substantially U-shaped with a middle portion and two arms extending from the middle portion of the U-shape. In some embodiments, the middle portion is in contact with the spacer plate when the susceptor is in the first position.

According to further examples, the substrate processing apparatus includes an annular recess ring interposed between the seal ring and the flow control ring in the recess of the flow control ring. In some embodiments, the annular recess ring comprises a metal.

According to further examples, the flow control ring comprises a ceramic. In some embodiments, the flow control ring comprises quartz. In some embodiments, the flow control ring comprises alumina.

According to further examples, the substrate processing apparatus includes a stepped annular ring configured. The stepped annular ring can contact the top surface of the flow control ring and a bottom of the recess of the flow control ring. In some embodiments, the stepped annular ring is or comprises a metal.

According to yet further examples, the substrate processing apparatus includes a controller connected to the susceptor motor. The susceptor motor can include a measuring device configured to measure a load on the susceptor motor. In such cases, the controller can be configured to adjust a torque on the susceptor motor based on the load measured when the susceptor is in the first position.

According to yet further examples, a flow control ring assembly is provided. An exemplary flow control ring assembly includes a flow control ring and a seal ring. The flow control ring can include an annular center region and a top portion comprising a recess. The annular center region can include a stepped structure comprising a first flat ledge portion and a second flat ledge portion and a vertical wall spanning therebetween. The second flat ledge portion can extend further toward a center of the flow control ring than the first flat ledge portion. The seal ring can be disposed in the recess.

According to yet further examples, a flow control ring assembly can include an annular recess ring interposed between the seal ring and the flow control ring in the recess. In accordance with examples, the seal ring is annular. The seal ring can include a body and at least two compressible members extending from the body. In some examples, a cross-section of the seal ring is substantially U-shaped with a middle portion and two arms extending from the middle portion of the U-shape. According to one or more examples, a flow control ring assembly includes a stepped annular ring. The stepped annular ring can be configured to contact the top surface of the flow control ring and a bottom of the recess of the flow control ring.

According to one or more embodiments, a method of substantially sealing an upper chamber from a lower chamber is provided. An exemplary method includes providing a substrate processing apparatus, activating the susceptor motor to move the susceptor from a lower position to an upper position, contacting the seal ring to the spacer plate, and substantially scaling the upper chamber from the lower chamber. The substrate processing apparatus can include an upper chamber, a lower chamber, a susceptor, a susceptor motor, a flow control ring, a spacer plate, and a seal ring. The susceptor can be configured to hold a substrate. The susceptor can include a top surface and a ledge protruding from a side of the susceptor. The flow control ring can include an annular center region, a first portion disposed on the top surface, a second portion disposed on the ledge, and a third portion comprising a recess. The seal ring can be disposed in the recess. The step of contacting seal ring to the spacer plate can thereby deform the seal ring.

### BRIEF DESCRIPTION OF THE DRAWINGS

FIG. 1 illustrates a cross-sectional view of a substrate processing apparatus in accordance with one or more examples of the disclosure;

FIG. 2 illustrates a cross-sectional view of the substrate processing apparatus of FIG. 1 in accordance with one or more examples of the disclosure;

FIG. 3 is a plan illustration showing an example of a susceptor and flow control ring in accordance with one or more examples of the disclosure;

FIG. 4 is an enlarged partial cross-section illustration showing an example of a flow control ring in accordance with examples of the disclosure;

FIGS. 5-7 are enlarged partial cross-sectional illustrative views of flow control ring assemblies in accordance with examples of the disclosure;

FIG. 8 is a partial cross-sectional illustration of the flow control ring assembly in accordance with additional examples of the disclosure;

FIG. 9 is a partial cross-sectional illustration of the flow control ring assembly in accordance with additional examples of the disclosure; and

FIG. 10 illustrates a method according to one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

Reference will now be made in detail to embodiments, which are illustrated in the accompanying drawings, wherein numerals refer to like elements throughout. In this regard, the examples may have different forms and should not be construed as being limited to the descriptions set forth herein. Accordingly, exemplary embodiments are described below, by referring to the figures, to explain aspects of the present description.

As used herein, the term “and/or” includes any and all combinations of one or more of the associated listed items. Expressions such as “at least one of,” when preceding a list of elements, modify the entire list of elements and do not modify the individual elements of the list. The terminology used herein is for the purpose of describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises”, “including”, and/or “comprising” used herein specify the presence of stated features, integers, steps, processes, members, components, and/or groups thereof, but do not preclude the presence or addition of one or more other features, integers, steps, processes, members, components, and/or groups thereof.

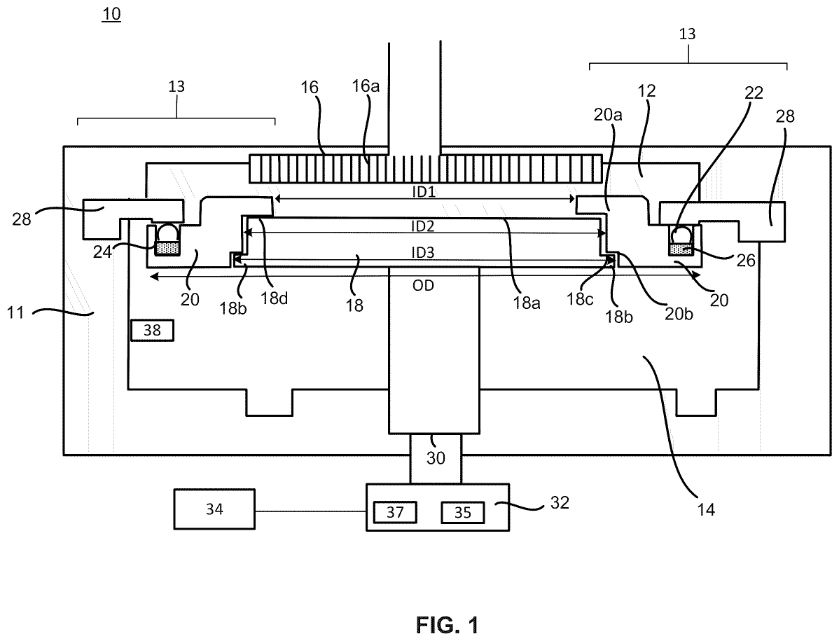

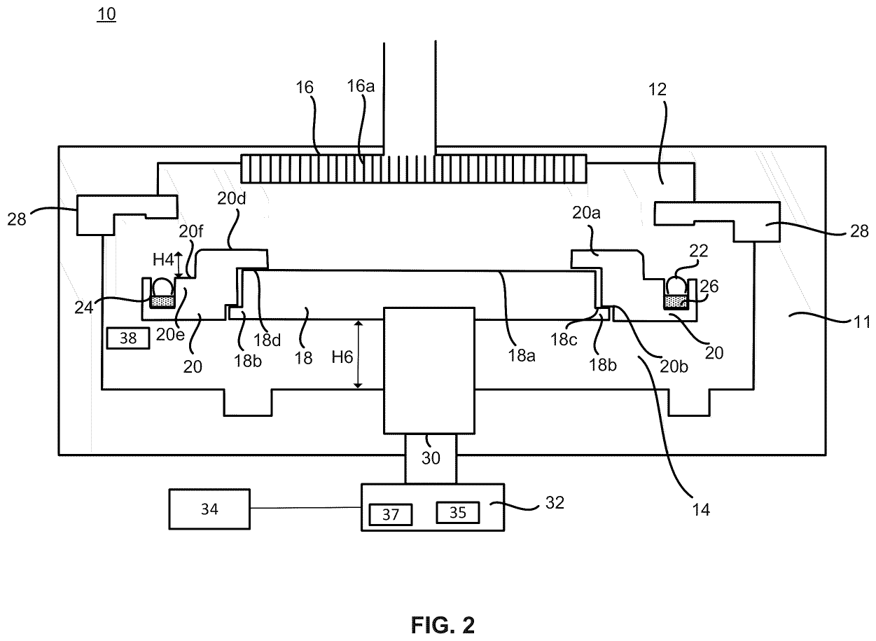

FIGS. 1 and 2 are cross-sectional illustrations of a substrate processing apparatus 10 according to at least one embodiment. In the illustrative example, the substrate processing apparatus 10 is configured as a film deposition apparatus that can perform a cyclic deposition cycle, such as chemical vapor deposition, that deposits material on a substrate. In some embodiments, the substrate processing apparatus 10 may be configured to perform a thermal chemical vapor deposition process. In some embodiments, the substrate processing apparatus 10 may be configured to perform a plasma-enhanced chemical vapor deposition process.

In some examples, the substrate processing apparatus 10 may be configured to process substrates with a temperature above 600° C. In some examples, the substrate processing apparatus 06 may be configured to process substrates with a temperature above 900° C.

In the illustrated example, the substrate processing apparatus 10 includes an upper chamber 12, a lower chamber 14, and at least one chamber wall 11. The substrate processing apparatus 10 may include a spacer plate 28 between the upper chamber 12 and the lower chamber 14. In some embodiments, the spacer plate 28 is attached to the chamber wall 11. In some embodiments, the spacer plate 28 is an integral portion of the chamber wall 11. A gas distribution device, such as a shower head 16 may be provided in the upper chamber 12. The shower head 16 may be provided with a plurality of holes 16a from which gas may pass into the upper chamber 12.

In an exemplary substrate processing apparatus 10, a susceptor 18 is provided to be opposed to the shower head 16. The susceptor 18 includes a top surface 18a configured to receive and support a substrate. In some embodiments, the susceptor 18 has a generally cylindrical shape. In some embodiments, the susceptor 18 further comprises a ledge 18b protruding from a side of the susceptor 18. The ledge 18b may comprise a flat top surface 18c. The susceptor 18 may be made of a ceramic material, such as Aluminum Nitrate (AlN). In some embodiments, the shower head 16 and the susceptor 18 may be electrodes to form a parallel plate structure capable of forming plasma.

In the substrate processing apparatus 10, a flow control ring assembly 13 is provided. The flow control ring assembly 13 may separate the upper chamber 12 from the lower chamber 14. The flow control ring assembly 13 may surround the side of the susceptor 18 and be disposed on the top surface 18a of the susceptor 18. In the illustrated example, the flow control ring assembly 13 includes a flow control ring 20 and a seal ring 22.

In an example, the flow control ring 20 has an annular center region with a first portion 20a disposed on the top surface 18a of the susceptor 18. The annular center region of the flow control ring 20 provides space for a substrate to be placed upon the top surface 18a of the susceptor 18. In some examples, the flow control ring 20 has a second portion 20b of the annular center region that is disposed on the ledge 18b of the susceptor 18. In some examples, the top surface of the flow control ring 20 may include a recess 24. The recess 24 may be positioned under the spacer plate 28.

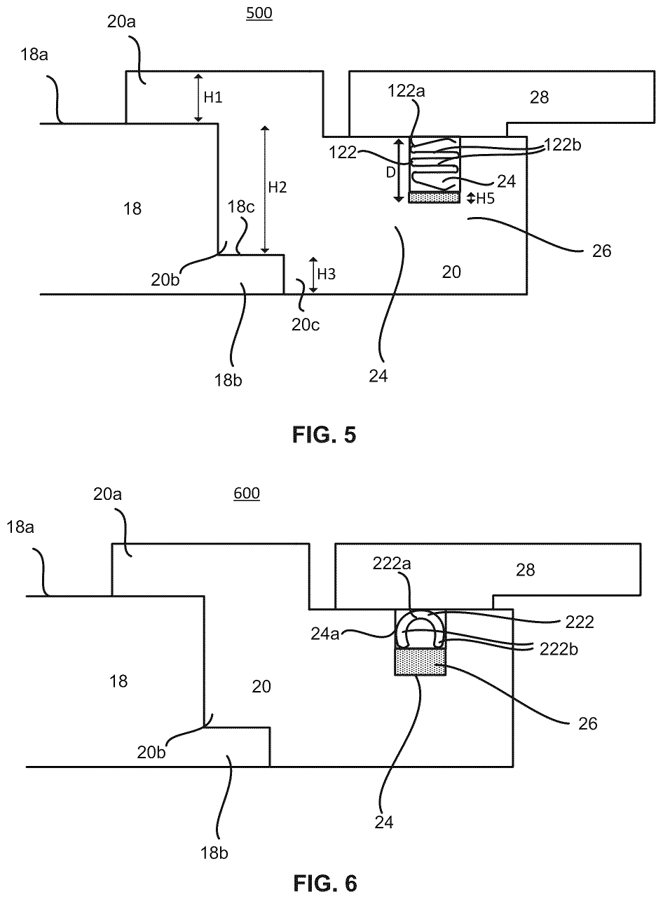

As illustrated in FIGS. 1 and 2, the flow control ring 20 includes an outer diameter (OD), a first inner diameter (ID1), a second inner diameter (ID2), and a third inner diameter (ID3), where ID1 is less than ID2 and ID2 is less than ID3. By way of example, ID1 can be about 300 mm to about 310 mm. By way of example, ID2 can be about 320 mm to about 330 mm. By way of example, ID3 can about 330 mm to about 340 mm. With reference to FIG. 5, a height (H1) of the first portion 20a can be about 2 mm to about 5 mm. A height (H2) of the second portion 20b can be about 10 mm to about 15 mm. A height (H3) of the third portion 20c can be about 1 mm to 5 about mm.

The first portion 20a of the flow control ring can have a top surface 20d. The flow control ring can include a fourth portion 20e having a top surface 20f. The top surface 20f of the fourth portion 20e can be at a lower height (H4) from a top surface 20d. The height (H4) can be about 3 mm to about 7 mm.

The recess 24 can be formed on top surface 20d or 20f of the flow control ring 20. The recess 24 can be radially exterior to the first portion 20a and the second portion 20b A depth (D) of the recess 24 can be about 5 mm to about 10 mm. The recess can be substantially annular in shape.

The flow control ring 20 can be made of a material capable of withstanding the forces on the flow control ring 20 and the processing temperatures. In some examples, the flow control ring 20 comprises a ceramic material. In some examples, the flow control ring 20 comprise quartz. In other examples, the flow control ring 20 may comprise alumina.

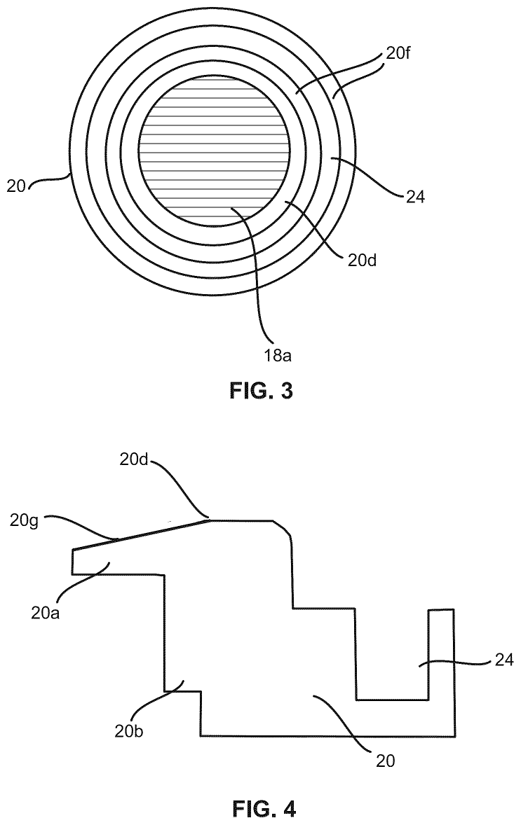

FIG. 3 is a plan illustration showing an example of the susceptor 18 and flow control ring 20. The flow control ring 20 surrounds and is disposed on the top surface 18a of the susceptor 18. The flow control ring 20 is not disposed in the center of the top surface 18a of the susceptor 18 to allow the susceptor 18 to hold a substrate. The top surface 20d of the flow control ring is radially interior to the top surface 20f of the flow control ring. The recess 24 may be disposed in the top surface 20f of the control ring.

FIG. 4 is an enlarged partial cross-section illustration showing an example of a flow control ring 20. In some examples, the top surface 20d of the flow control ring 20 can comprise an inclined surface 20g. The inclined surface 20g may increase the thickness of the first portion 20a from the inner radius of the flow control ring 20 towards the outer radius of the flow control ring 20. The inclined surface 20g may slope upward from the inner radius of the flow control ring 20 towards the outer radius of the flow control ring 20. The inclined surface 20g may help with directing flow in the chamber. The inclined surface may help direct waste gases from the chamber to the exhaust.

Turning back to FIGS. 1 and 2, the seal ring 22 may be disposed within the recess 24. The seal ring 22 may comprise any material suitable for forming a seal, for example, a material that can be compressed and withstand high forces. The seal ring 22 may be made of a material able to deform when compressed. The seal ring 22 may be made of, for example, INCONEL® X-750, as made by Ulbrich Stainless Steels & Special Metals, Inc.

In some examples, an annular recess ring 26 may be disposed within the recess 24 beneath the seal ring 22. The recess ring 26 may be of substantially the same annular shape as the annular recess 24. A height (H5), for example as shown in FIG. 4, of the recess ring 26 can be 1 mm to 5 mm. The recess ring 26 may be made of any material suitable of withstand the temperature and forces in the substrate processing apparatus 10. In some examples, the recess ring 26 may be made of a metal and metal alloys, such as Titanium, Hastelloy C-22 Hastelloy C-276. In some examples the recess ring 26 may be made of ceramic, such as Alumina and Aluminum Nitrate (AlN).

In an exemplary substrate processing apparatus 10, the susceptor 18 may be configured to move vertically. The susceptor 18 may be supported by a sliding shaft 30. The susceptor 18 and the flow control ring assembly can be lifted and lowered by a susceptor motor 32.

In some examples, the susceptor 18 may be moved by the susceptor motor 32 into at least two positions. FIG. 1 depicts the susceptor in a first position. In a first position, the seal ring 22 contacts the spacer plate 28. In the first position, the seal ring 22 may be deformed by the force of the spacer plate 28 provided by the susceptor motor 32. In the first position, the upper chamber 12 may be sealed or substantially sealed from the lower chamber 14. In some examples, the substrate processing apparatus 10 may process substrates when the substrate is in the first position.

In the first position, there will be a downward force from spacer plate 28 to the seal ring 22. In some examples, the recess ring 26 receives the downward force of the seal ring 22 and (e.g., evenly) distributes the force to the flow control ring 20. In some examples, the force from the seal ring 22 is received by the flow control ring 20. The force on the flow control ring 20 will then be transferred to the susceptor 18. The flow control ring 20 will distribute downward forces onto the susceptor 18. In some examples, the downward force from the flow control ring 20 may be, for example, substantially evenly distributed to the susceptor 18 about a perimeter of the top surface 18a. In some examples, the downward force from the flow control ring 20 may be, for example, substantially evenly distributed to the susceptor 18 by a perimeter region 18d of the top surface 18a and the ledge 18b.

FIG. 2 illustrates the substrate processing apparatus 10 when the susceptor 18 in a second position. In the second position, the susceptor 18 is lowered such that the seal ring 22 does not contact the spacer plate 28. In the second position, the upper chamber 12 is not sealed from the lower chamber 14. In FIG. 2, the upper chamber 12 and the lower chamber 14 are fluidly connected to each other.

Continuing reference to FIGS. 1 and 2, in some examples, the susceptor motor 32 may comprise a load sensor 35 to measure the load on the susceptor motor 32. When the seal ring 22 contacts the spacer plate 28, the seal ring 22 deforms, and the flow control assembly 13 applies a downward force onto the susceptor 18, which puts a load onto the susceptor motor 32, which will be measured by the load sensor 35. The susceptor motor 32 can increase an output, such that the seal ring is deformed further and the load on the susceptor motor 32 increases. In some examples, the susceptor motor can also sense the height of the susceptor 18 using a height sensor 37. In some examples, the height sensor 37 or another sensor is used to measure susceptor 18 height, e.g., a height (H6) relative to the spacer plate 28.

In some examples, a controller 34 is connected to the susceptor motor 32. In some embodiments, the controller 34 is connected to the separate height sensor 38 to measure susceptor 18 height. In other examples, the controller 34 is connected to the height sensor 37 to measure susceptor 18 height. Controller 34 includes electronic circuitry and software to selectively operate the susceptor motor 32. Controller 34 can include modules such as a software or hardware component, e.g., a FPGA or ASIC, which performs certain tasks. A module can advantageously be configured to reside on the addressable storage medium of the controller 34 and be configured to execute one or more processes.

The controller 34 may be configured to control the position of the susceptor 18, by controlling the output of the susceptor motor 32. In some examples, the controller 34 is configured to move the susceptor 18 between the first position and the second position. In some examples, the controller 34 may be configured to move the susceptor 18 to other positions. In some examples, the controller 34 may be configured to move the susceptor 18 to predetermined heights. In some examples, the controller 34 may be configured to move the susceptor 18 to the first position by controlling the susceptor motor 32 to move the susceptor 18 up until the seal ring 22 contacts the spacer plate 28 and exerts a sufficient force onto the seal ring 22 such that a predetermined load setpoint is measured on the sensor. The predetermined load setpoint may indicate that there is a sufficient downward force on the seal ring 22 such that the upper chamber 12 is sealed or substantially sealed from the lower chamber 14.

In some examples, while in the first position, the controller 34 is configured to maintain a sufficient output of the susceptor motor 32 to maintain a sufficient force between the seal ring 22 and the spacer plate 28, such that the upper chamber 12 is sealed or substantially sealed from the lower chamber 14 during substrate processing.

In some examples, the controller 34 may be configured to adjust the output of the susceptor motor 32 using feedback loops from the load on the susceptor motor 32 and/or the susceptor 18 height. In an example, the compression of the seal ring 22 may be such that the amount of compression of the seal ring 22 is proportional to the force on the seal ring 22 and a spring constant for the seal ring 22. The spring constant of the seal ring 22 may change over time due to fatigue or other changes to the seal ring 22. Based on the measured load on the susceptor motor 32 and the measured susceptor 18 height, the controller 34 may adjust the output of the susceptor motor 32 to maintain a sufficient force on the seal ring 22 such that the upper chamber 12 maintains the seal or substantial seal from the lower chamber 14 in real time.

FIG. 5 is an enlarged partial cross-sectional illustrative view of an example of the flow control ring assembly 500 in accordance with one or more examples of the disclosure. FIG. 5 depicts the susceptor 18, flow control ring 20, and other components of the substrate processing apparatus 10. The susceptor 18 includes the top surface 18a configured to receive and support a substrate. The susceptor 18 further comprises the ledge 18b protruding from a side of the susceptor 18. The ledge may comprise a flat top surface 18c. The flow control ring 20 can be as described above.

In some examples, the seal ring 122 may comprise a body 122a and at least two compressible members 122b extending from the body 122a. The seal ring 122 may be disposed within the recess 24 such that the at least two compressible members 122b extend horizontally. The at least two compressible members 122b are compressed when the susceptor 18 is in the first position.

FIG. 6 is an enlarged partial cross-sectional illustrative view of another example of a flow control ring assembly 600, suitable for use as flow control ring assembly 13. FIG. 6 depicts another example of the seal ring 222, suitable for use as the seal ring 22. The seal ring 222 may be substantially U-shaped with a middle portion 222a and two arms 222b extending from a middle portion 222a of the U-shape. As illustrated, the middle portion can be in contact with the spacer plate 28 when the susceptor 18 is in the first position. When the susceptor 18 is in the first position, the middle portion of the seal ring 222 contacts the spacer plate 28, causing the two arms to deform and press against a sidewall 24a of the recess 24.

In the example depicted in FIG. 6, the seal ring 222 does not have any deep or narrow spaces between arms 222b. As the seal ring 222 is compressed and relaxed as the susceptor 18 moves into and out of the first position, any depositions on the seal ring 222 may flake off and generate particles. The seal ring 222 may be easily cleaned using an in-situ processing. The seal ring 222 is shaped such that the there are no deep grooves or contours that cannot be reached by an in-situ processing. As such, the seal ring 222 may produce less particles.

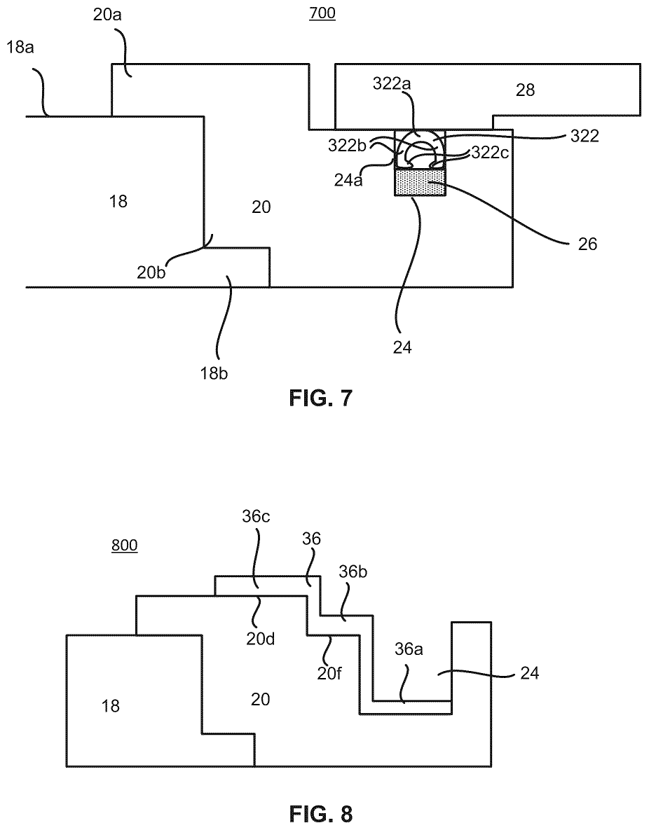

FIG. 7 is an enlarged partial cross-sectional illustrative view of yet another example of a flow control ring assembly 700, suitable for use as flow control ring assembly 13. FIG. 7 depicts yet another example of a seal ring 322, suitable for use as seal ring 22. The seal ring 322 may substantially be U-shaped with a middle portion 322a and two arms 322b extending from the middle portion 322a of the U-shape, and a member 322c extending from the end of each arm 322b. As illustrated, the middle portion 322a is in contact with the spacer plate 28 when the susceptor is in the first position. When the susceptor 18 is in the first position, the middle portion 322a of the seal ring 322 contacts the spacer plate 28, causing the two arms 322b to deform and press against sidewall 24a of the recess 24. The members 322c are further pressed into the bottom of the recess 24 or into the recess ring 26. Further, as the seal ring 322 is compressed, the seal ring 322 will deform to take up more volume of the recess 24 and cause there to be less need for an in-situ cleaning.

In the example depicted in FIG. 7, the seal ring 322 does not have any deep or narrow spaces between arms 322b. As the seal ring 322 is compressed and relaxed as the susceptor 18 moves into and out of the first position, any depositions on the seal ring 322 may flake off and generate particles. The seal ring 322 may be easily cleaned using an in-situ processing. The seal ring 322 is shaped such that the there are no deep grooves or contours that cannot be reached by an in-situ processing. As such, the seal ring 322 may produce less particles.

FIG. 8 is a partial cross-sectional illustration of the flow control ring assembly 800, suitable for use as the flow control ring assembly 13, in accordance with additional examples of the disclosure. In some examples, the flow control ring assembly 800 includes a stepped annular ring 36. The stepped annular ring 36 may be disposed on the top surface of the flow control ring 20 and the bottom of the recess 24 of the flow control ring 20. The stepped annular ring 36 may distribute the downward force from the seal ring 22 and/or recess ring 26 across a larger surface of the flow control ring 20.

The stepped annular ring 36 may be made of any suitable material. In some examples, the stepped annular ring 36 comprises a metal and alloy, such as Titanium, Hastelloy C-22 and Hastelloy C-276. As illustrated in FIG. 8, the stepped annular ring may comprise a first portion 36a, a second portion 36b, and a third portion 36c. The first portion 36a may be disposed in the recess 24 of the flow control ring. The second portion 36b may be disposed on the top surface 20f of the flow control ring 20. The third portion 36c may be disposed on the top surface 20d of the flow control ring 20.

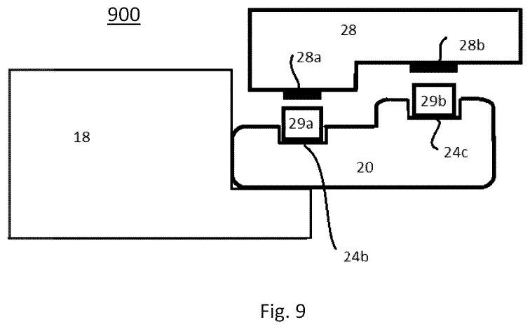

FIG. 9 is a partial cross-sectional illustration of the flow control ring assembly 900, suitable for use as the flow control ring assembly 13, in accordance with additional examples of the disclosure. In some examples, the flow control ring assembly 900 includes a flow control ring 20, a spacer plate 28, and at least one gasket 29 that makes contact with the flow control ring 20 and the spacer plate 28. In some examples, the flow control ring can include two recesses (24b, 24c). In some examples, the spacer plate 28 can include protrusions 28a and 28b. A gasket 29a can be disposed in one recess 24b and another gasket 29b can be disposed in the other recess 29c. Each gasket 29a, 29b can be made of a mica-based material, such as Micatherm SO or Micatherm S15, as made by Planichem SRL.

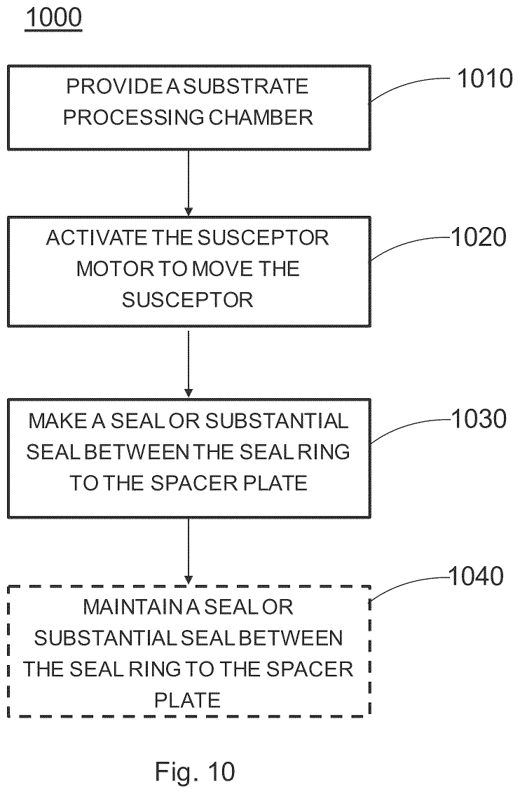

FIG. 10 illustrates a method according to one or more embodiments of the disclosure. Method 1000 can be used for sealing or substantially sealing an upper chamber from a lower chamber. Substrates may be processed in an upper chamber, which may desirably be sealed or substantially sealed from a lower chamber. Without a substantial seal, process gases may leak between the upper chamber and the lower chamber and may cause contamination or particles. The method 1000 includes the steps of providing a substrate processing apparatus (step 1010), activating a susceptor motor to move a susceptor from a lower position to an upper position (step 1020), making or forming a seal or substantial seal between the seal ring to the spacer plate (step 1030), and adjusting the output of the susceptor motor to maintain a seal or substantial seal ring to the spacer plate (step 1040).

The step 1010 of providing a substrate processing apparatus includes providing a substrate processing apparatus that includes an upper chamber, a lower chamber, a susceptor configured to hold a substrate, wherein the susceptor comprises a top surface and a ledge protruding from a side of the susceptor, a susceptor motor, a flow control ring, wherein the flow control ring comprises an annular center region, a first portion disposed on the top surface, a second portion disposed on the ledge, and a third portion comprising a recess; a spacer plate, and a seal ring, wherein the seal ring is disposed in the recess. The flow control ring and the spacer plate may be disposed between the upper and lower chamber. The susceptor motor may be configured to vertically move the susceptor, the flow control ring, and the seal ring. The susceptor motor may be connected to a controller. The susceptor motor may comprise a sensor to measure the load on the motor. The susceptor motor may comprise a height sensor to measure the position of the susceptor. A separate height sensor may be used to measure susceptor height, as disclosed above.

The processing apparatus may be configured such that the susceptor has at least a lower position and an upper position. In the lower position, the seal ring does not contact the spacer plate. In the upper position, the seal ring contacts the spacer plate.

The step 1020 includes activating a susceptor motor. The susceptor motor may move the susceptor (and the flow control ring assembly) from the lower position to the upper position.

The step 1030 includes making a seal or substantial seal between the seal ring to the spacer plate. After the seal ring contacts the spacer plate, the output of the susceptor motor may be increased to increase the force between the seal ring and the spacer plate. The seal ring may deform and create a seal or substantial seal between the seal ring and the flow control ring.

In some embodiments, method 1000 includes a step 1040 of maintaining the seal or substantial seal between the seal ring and the spacer plate. For example, during substrate processing, the controller may adjust the output of the susceptor motor using feedback loops from the load on the susceptor motor and the susceptor height. In an example, the compression of the seal ring may be such that the amount of compression of the seal ring is proportional to the force on the seal ring and a spring constant for the seal ring. The spring constant of the seal ring may change over time due to fatigue or other changes to the seal ring. Based on the measured load on the susceptor motor and the measured susceptor height, the controller may adjust the output of the susceptor motor, for example, using closed loop-control, to maintain a sufficient force on the seal ring such that the upper chamber maintains the seal or substantial seal from the lower chamber in real time. In some cases, when a spring constant is determined to be above or below a threshold value (e.g., from a force on the susceptor motor and a measured height of the susceptor), an indication can be provided to a user or to a user interface.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A substrate processing apparatus, the substrate processing apparatus comprising:
an upper chamber;
a lower chamber;
a susceptor configured to hold a substrate, wherein the susceptor comprises a top surface and a ledge protruding from a side of the susceptor;
a flow control ring, wherein the flow control ring comprises an annular center region, a first portion disposed on the top surface, a second portion disposed on the ledge, and a third portion comprising a recess;
a spacer plate; and
a seal ring,
wherein the seal ring is disposed in the recess.

2. The substrate processing apparatus of claim 1, further comprising a susceptor motor configured to raise and lower the susceptor from at least a first position to a second position.

3. The substrate processing apparatus of claim 2, wherein the seal ring contacts the spacer plate when the susceptor is in the first position, and wherein the seal ring substantially seals the upper chamber from the lower chamber when the susceptor is in the first position.

4. The substrate processing apparatus of claim 2, wherein the seal ring is annular and wherein the seal ring comprises a body and at least two compressible members extending from the body.

5. The substrate processing apparatus of claim 4, wherein the at least two compressible members extend horizontally, and wherein the at least two compressible members are compressed when the susceptor is in the first position.

6. The substrate processing apparatus of claim 2, wherein the seal ring is annular, wherein a cross-section of the seal ring is substantially U-shaped with a middle portion and two arms extending from the middle portion of the U-shape, and wherein the middle portion is in contact with the spacer plate when the susceptor is in the first position.

7. The substrate processing apparatus of claim 1, further comprising an annular recess ring interposed between the seal ring and the flow control ring in the recess of the flow control ring.

8. The substrate processing apparatus of claim 7, wherein the annular recess ring comprises a metal.

9. The substrate processing apparatus of claim 1, wherein the flow control ring comprises a ceramic.

10. The substrate processing apparatus of claim 9, wherein the flow control ring comprises quartz.

11. The substrate processing apparatus of claim 9, wherein the flow control ring comprises alumina.

12. The substrate processing apparatus of claim 1, further comprising a stepped annular ring configured to contact the top surface of the flow control ring and a bottom of the recess of the flow control ring.

13. The substrate processing apparatus of claim 12, wherein the stepped annular ring comprises a metal.

14. The substrate processing apparatus of claim 1, further comprising a controller connected to the susceptor motor,
wherein the susceptor motor comprises a measuring device configured to measure a load on the susceptor motor, and
wherein the controller is configured to adjust a torque on the susceptor motor based on the load measured when the susceptor is in the first position.

15. A flow control ring assembly comprising:
a flow control ring, wherein the flow control ring comprises an annular center region and a top portion comprising a recess, wherein the annular center region comprises a stepped structure comprising a first flat ledge portion and a second flat ledge portion and a vertical wall spanning therebetween, wherein the second flat ledge portion extends further toward a center of the flow control ring than the first flat ledge portion; and
a seal ring disposed in the recess.

16. The flow control ring assembly of claim 15, further comprising an annular recess ring interposed between the seal ring and the flow control ring in the recess.

17. The flow control ring assembly of claim 15, wherein the seal ring is annular and wherein the seal ring comprises a body and at least two compressible members extending from the body.

18. The flow control ring assembly of claim 15, wherein the seal ring is annular, wherein a cross-section of the seal ring is substantially U-shaped with a middle portion and two arms extending from the middle portion of the U-shape.

19. The flow control ring assembly of claim 15, further comprising a stepped annular ring configured to contact the top surface of the flow control ring and a bottom of the recess of the flow control ring.

20. A method of substantially sealing an upper chamber from a lower chamber, the method comprising:
providing a substrate processing apparatus comprising:
an upper chamber,
a lower chamber,
a susceptor configured to hold a substrate, wherein the susceptor comprises a top surface and a ledge protruding from a side of the susceptor,
a susceptor motor,
a flow control ring, wherein the flow control ring comprises an annular center region, a first portion disposed on the top surface, a second portion disposed on the ledge, and a third portion comprising a recess;
a spacer plate, and
a seal ring, wherein the seal ring is disposed in the recess;
activating the susceptor motor to move the susceptor from a lower position to an upper position; and
contacting the seal ring to the spacer plate, thereby deforming the seal ring, and substantially scaling the upper chamber from the lower chamber.
